(19) United States
(12) Patent Application Publication
(10) Pub. No.: US 2015/0054815 A1
(43) Pub. Date: Feb. 26, 2015

(54) DRIVING METHOD OF ORGANIC EL DISPLAY DEVICE AND ORGANIC EL DISPLAY DEVICE

(71) Applicant: Japan Display Inc., Tokyo (JP)

(72) Inventors: Hironori TOYODA, Tokyo (JP); Toshihiro SATO, Tokyo (JP)

(21) Appl. No.: 14/463,700

(22) Filed: Aug. 20, 2014

(30) Foreign Application Priority Data
Aug. 21, 2013 (JP) 2013-171597

(51) Int. Cl. G09G 3/32; H05B 33/08

(52) U.S. Cl. CPC G09G 3/3208; H05B 33/0896; G09G 2310/0264
USPC 345/212; 315/294; 345/82

(57) ABSTRACT

The adjustment of a color temperature is made possible in a display panel using a white light-emitting OLED. The white light-emitting OLED includes a light-emitting layer containing light-emitting materials of respective colors of R, G, and B. By changing the current density of a drive current to be supplied to the white light-emitting OLED, light emission of the OLED is adjusted to a color temperature in response to an instruction from a user. A period PD in which the OLED emits light is changed in inverse proportion to a change in drive current so as to maintain emission luminance in one frame for the emission intensity of the OLED changing in response to the drive current.

### CROSS-REFERENCE TO RELATED APPLICATION

The present application claims priority from Japanese application JP2013-171597 filed on Aug. 21, 2013, the content of which is hereby incorporated by reference into this application.

### BACKGROUND OF THE INVENTION

1. Field of the Invention

The present invention relates to an organic electroluminescence (EL) display device and a driving method thereof.

2. Description of the Prior Art(s)

An organic EL display device generates a plurality of colors such as red (R), green (G), and blue (B) using lights emitted by organic light-emitting diodes (OLEDs) as organic light-emitting elements and displays a color image. Each of pixels that are two-dimensionally arranged in an image display area is composed of plural kinds of sub-pixels that emit lights of different colors from each other. The emission intensities of the sub-pixels can be controlled independently of each other, and the pixel can express various colors according to the balance of the emission intensities.

As one of the ways to generate a plurality of colors, there is a configuration of combining white light emitting OLEDs with color filters. In the configuration, the OLEDs of the respective sub-pixels emit common white light, and color filters different in transmission color are arranged corresponding to the colors of the sub-pixels on the side of a display surface through which the emitted light of the OLED exits.

Examples of the structure of the white light-emitting OLED include a structure (a single-layer type) in which a light-emitting layer is formed of a single layer containing a plurality of light-emitting materials and a structure (a stacked type) which has a plurality of light-emitting layers of different colors (different colored light-emitting layers) that are stacked. The OLEDs of the stacked type are divided into two types in terms of structure: one type has a structure (a single unit structure) in which the plurality of different colored light-emitting layers are directly stacked; and the other type has a structure (a multi unit structure or tandem structure) in which the plurality of different colored light-emitting layers are electrically connected in series via a light-transmissive intermediate layer.

When it is intended in the white light-emitting OLED of the single-layer type to obtain white light emission of a desired color temperature by adjusting the mixing amounts of the plurality of light-emitting materials, a fine adjustment is required to determine a proper condition of the mixing amounts. Moreover, there is also a problem that a deposition apparatus capable of strictly controlling the mixing amount is required to satisfy the proper condition. Therefore, the stacked type is mainly considered at present, and especially, the tandem structure is attracting attention.

### SUMMARY OF THE INVENTION

A color temperature desired for a white light-emitting OLED can depend on a product of a display device using the white light-emitting OLED. This is because, when designing an organic EL display device, the characteristics of colors of an image are affected not only by the characteristics of the OLED but also by various factors such as the characteristics of color filters or the characteristics of video signal processing, and in addition, aimed characteristics themselves such as color reproducibility may be different depending on the product in the first place.

However, it is troublesome to design or manufacture display panels in which the color temperature of the white light-emitting OLED is changed according to the product, and there is also a problem of causing an increase in cost.

Moreover, it is convenient that an end user of an organic EL display device can adjust the hue of an image in the individual organic EL display device. However, when it is intended to realize the adjustment through video signal processing, an arithmetic load is increased by that amount, and therefore, there is a problem such as requiring a higher-speed arithmetic unit or increasing the scale of a processing circuit.

The invention has been made to solve the problems described above, and the invention provides a driving method and a structure by which a color temperature of a white light-emitting OLED can be adjusted in an organic EL display device.

(1) A driving method of an organic EL display device according to an aspect of the invention is a driving method of an organic EL display device in which organic light-emitting elements each of which includes a light-emitting layer containing a plurality of light-emitting materials of different colors and emits light in response to a drive current are two-dimensionally arranged, the method including: changing the drive current to be supplied to the organic light-emitting element so that light emission of the organic light-emitting element produces a hue in response to an instruction from a user; and changing a light emission duty of the organic light-emitting element in inverse proportion to a change in the drive current so as to maintain emission luminance before and after the change in the drive current.

(2) The driving method according to (1) may be applied to the organic EL display device in which the light-emitting layer includes a plurality of different colored light-emitting layers that are stacked, the plurality of different colored light-emitting layers containing light-emitting materials of different colors from each other.

(3) In (2), the organic light-emitting element may have a tandem structure in which a plurality of light-emitting units of different colors are connected in series.

(4) In (1) to (3), the contents of the plurality of light-emitting materials in the light-emitting layer may be such that the shorter the wavelength of a luminescent color is, the higher the content is.

(5) An organic EL display device according to an aspect of the invention is an organic EL display device in which an organic light-emitting element that includes a light-emitting layer containing a plurality of light-emitting materials of different colors and emits light in response to a drive current is arranged in each of pixels, including: a pixel circuit to which a light emission control pulse having a pulse width defining a light emission duty is input and that supplies to the organic light-emitting element the drive current at a current density in response to a pixel value in response to an image to be displayed and a pulse voltage of the light emission control pulse; a storage unit that stores a correlation between the pulse voltage and a luminescent color of the organic light-emitting element changing in response to the drive current; and a driver circuit to which an instruction relating to a luminescent color from a user is input and that supplies to the pixel circuit the light emission control pulse in response to the instruction, the driver circuit setting, based on the correlation, the pulse voltage corresponding to the luminescent color according to the instruction and changing, for a change in the pulse voltage, the pulse width in inverse proportion to the change in the drive current in response to the pulse voltage.

### BRIEF DESCRIPTION OF THE DRAWINGS

FIG. 1 is a schematic plan view of a display panel of an organic EL display device as an embodiment of the invention.

FIG. 2 is a schematic vertical sectional view of the display panel taken at a position along the line II-II shown in FIG. 1.

FIG. 3 is a schematic vertical sectional view of an OLED taken along the line III-III shown in FIG. 2.

FIG. 4 is a schematic circuit diagram of the organic EL display device as the embodiment of the invention, mainly showing a schematic configuration of a portion formed in the display panel.

FIG. 5 is a schematic circuit diagram of a pixel circuit.

FIG. 6 is a schematic timing diagram explaining the operation of a pixel circuit.

FIG. 7 is a graph showing an example of the result of measuring the relationship between the current density of a drive current to be supplied to the OLED and the chromaticity of the OLED.

FIG. 8 is a schematic view showing an example of processing performed by a control unit for changing a light emission duty in response to the current density.

### DETAILED DESCRIPTION OF THE INVENTION

Hereinafter, an embodiment of the invention (hereinafter referred to as the embodiment) will be described based on the drawings.

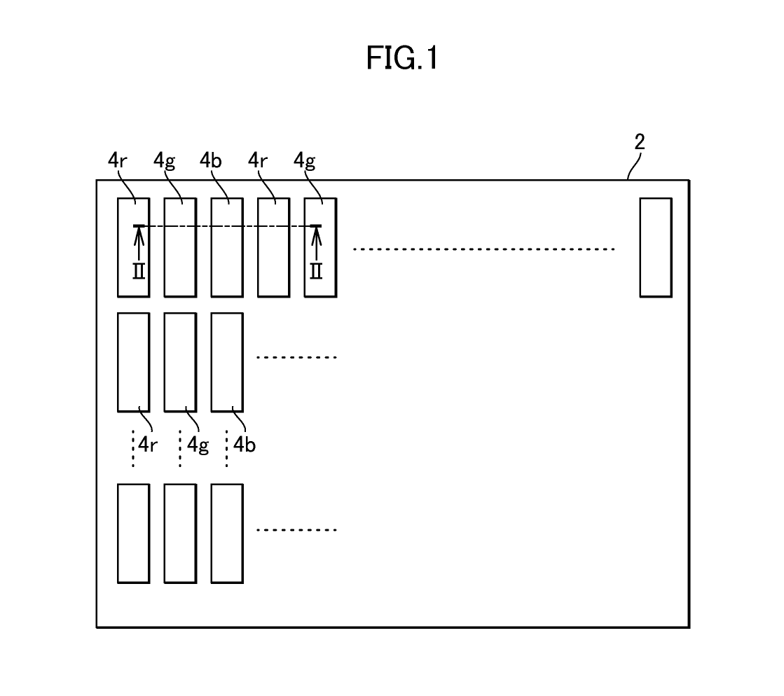

FIG. 1 is a schematic plan view of a display panel 2 of an organic EL display device as the embodiment. The display panel 2 of the embodiment displays a color image. Each pixel in the color image is composed of, for example, pixels (sub-pixels) emitting lights corresponding to R, G, and B. In the following description, R, G, and B sub-pixels are expressed as R, G, and B pixels for simplifying the description.

In the embodiment, an example will be described in which R pixels 4r, G pixels 4g, and B pixels 4b are arranged in a stripe pattern in a display area. In the arrangement, pixels of the same kind (color) are arranged in the vertical direction of an image, and the R, G, and B pixels are periodically arranged in the horizontal direction. In FIG. 1, each of the R pixel 4r, the G pixel 4g, and the B pixel 4b schematically represents an effective light-emitting area, and each area between the pixels corresponds to a bank.

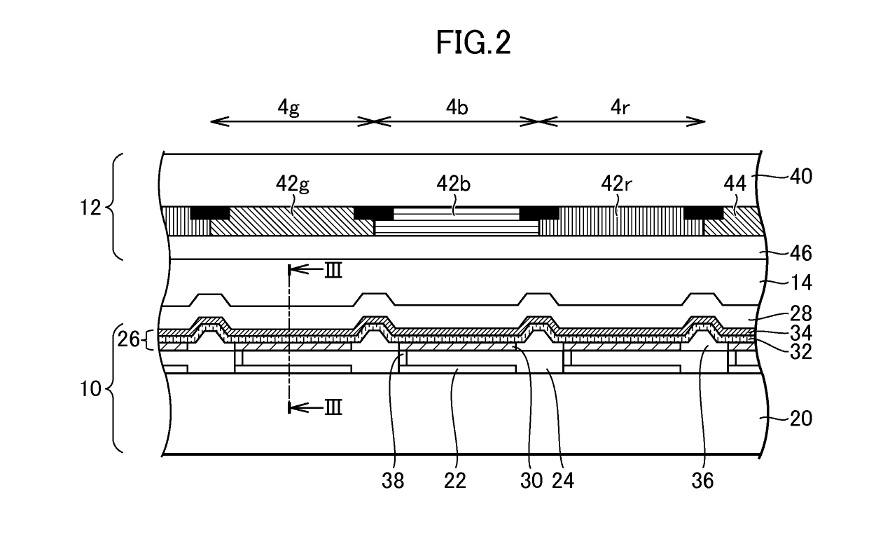

FIG. 2 is a schematic vertical sectional view of the display panel 2 taken at a position along the line II-II shown in FIG. 1. The display panel 2 has a structure in which a TFT substrate 10 and a color filter substrate 12 are bonded together with a filling material 14 interposed therebetween.

The TFT substrate 10 includes a circuit portion 22, an insulating film 24, an OLED portion 26, and a sealing film 28 that are stacked on a glass substrate 20.

The circuit portion 22 is an electronic circuit that supplies a current in response to a video signal to the OLED portion 26 to cause the OLED portion 26 to emit light. The circuit portion 22 is formed of circuit elements such as wires or TFTs, and formed on a surface of the glass substrate 20. For example, a power line, pixel circuits, and the like are formed in the display area. Moreover, on the outside of the display area, a driver circuit for the display area is formed, or a flexible board or the like connected to an external circuit is connected.

The insulating film 24 is stacked on the surface of the glass substrate 20 to cover the circuit portion 22, and electrically insulates between pixel circuits each provided in each pixel or between a lower electrode 30 and the circuit portion 22. The insulating film 24 is formed of, for example, silicon oxide (SiO₂), silicon nitride (SiN), or the like.

The OLED portion 26 is configured to include the lower electrode 30, an organic material stacked portion 32, an upper electrode 34, and a bank 36.

The lower electrode 30, the upper electrode 34, and the organic material stacked portion 32 interposed therebetween constitute an OLED. The upper electrode 34 is basically a common electrode in common contact with the organic material stacked portions 32 of all pixels in the display area. On the other hand, the lower electrode 30 is separately formed in each of the pixels, and electrically connected with the circuit portion 22 via a contact hole 38. In the embodiment, the upper electrode 34 serves as a cathode of the OLED, while the lower electrode 30 serves as an anode. The upper electrode 34 and the lower electrode 30 are formed using, for example, a transparent conductive material such as IZO (indium zinc oxide) or ITO (indium tin oxide). The organic material stacked portion 32 includes a light-emitting layer described later. Holes and electrons are injected into the light-emitting layer according to a voltage applied to the electrodes, and recombination of the injected holes and electrons produces light emission.

The bank 36 is formed of an insulating layer at boundaries between the R, G, and B pixels, and electrically isolates the lower electrodes 30 from each other.

The sealing film 28 is stacked on the OLED portion 26. To deal with the deterioration of the characteristics of the OLED due to moisture, the sealing film 28 has a moisture-proof function to protect the OLED against moisture contained in the filling material 14. For example, the sealing film 28 is formed of SiN.

In the color filter substrate 12, a stacked structure including a color filter 42, a black matrix 44, and an overcoat layer 46 are formed on a glass substrate 40.

The color filter 42 is stacked on a surface of the glass substrate 40. The color filter 42 is formed of a light-transmissive resin material or the like, and colored in a plurality of colors with pigments or the like. For example, the color filter 42 is formed of a color resist. In the embodiment, a red (R) filter 42r, a green (G) filter 42g, and a blue (B) filter 42b are provided, as the color filter 42, corresponding to the R pixel 4r, the G pixel 4g, the B pixel 4b.

At each boundary between the color filters, the black matrix 44 is formed by patterning a light-shielding film formed of chromium (Cr) or the like.

The overcoat layer 46 covers a surface of the glass substrate 40 on which the color filter 42 and the black matrix 44 described above are stacked. The overcoat layer 46 is made of a transparent resin material such as, for example, acrylic resin.

The TFT substrate 10 and the color filter substrate 12 are arranged to face each other with a gap therebetween. A dam material (sealing material) (not shown) is provided so as to surround the display area in the gap to seal a gap in the display area. The filling material 14 fills the gap inside the dam material. The dam material and the filling material 14 are cured to bond the substrates together.

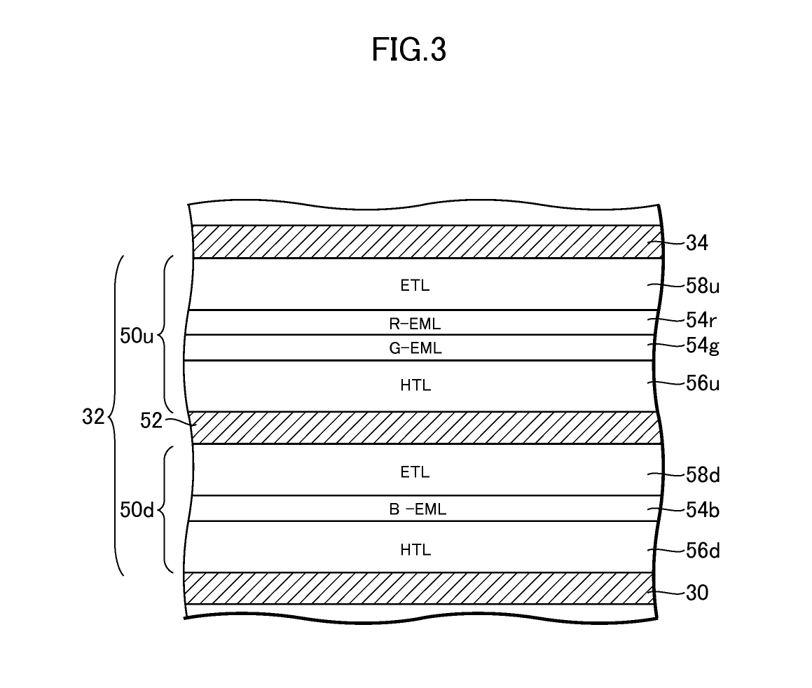

FIG. 3 is a schematic view showing a structure of the OLED in the display panel 2, representing a vertical section along the line III-III in FIG. 2. Although a vertical section at the G pixel is shown in FIG. 3, the structure of the OLED is common to the R, G, and B pixels.

The OLED of the embodiment has a tandem structure, in which a plurality of light-emitting units 50 as the organic material stacked portion 32 are connected in series between the lower electrode 30 and the upper electrode 34 via a light-transmissive and conductive intermediate layer 52. Specifically, a blue light-emitting unit (B light-emitting unit) 50d and a red-green light-emitting unit (RG light-emitting unit) 50u are stacked in the OLED in each of the pixels of the display panel 2.

Each of the light-emitting units 50 includes an emissive layer (EML) 54, and a hole transport layer (HTL) 56 and an electron transport layer (ETL) 58 that are provided on both sides of the emissive layer (EML) 54. Specifically, the B light-emitting unit 50d includes a B-emissive layer (B-EML) 54b that emits B light, a hole transport layer 56d, and an electron transport layer 58d. The hole transport layer 56d, the B-emissive layer 54b, and the electron transport layer 58d are stacked in this order on the lower electrode 30. The RG light-emitting unit 50u includes an R-emissive layer (R-EML) 54r that emits R color light, a G-emissive layer (G-EML) 54g that emits G color light, a hole transport layer 56u, and an electron transport layer 58u. The hole transport layer 56u, the G-emissive layer 54g, the R-emissive layer 54r, and the electron transport layer 58u are stacked in this order on the intermediate layer 52 that is stacked on the electron transport layer 58d of the B light-emitting unit 50d. Each of the different colored emissive layers is formed of a host material and a dopant material dispersed therein. For example, it is possible to provide a white light-emitting OLED having a tandem structure in which a fluorescent material is used as a dopant material of the B-emissive layer and a phosphorescent material is used as a dopant material of each of the R-emissive layer and the G-emissive layer.

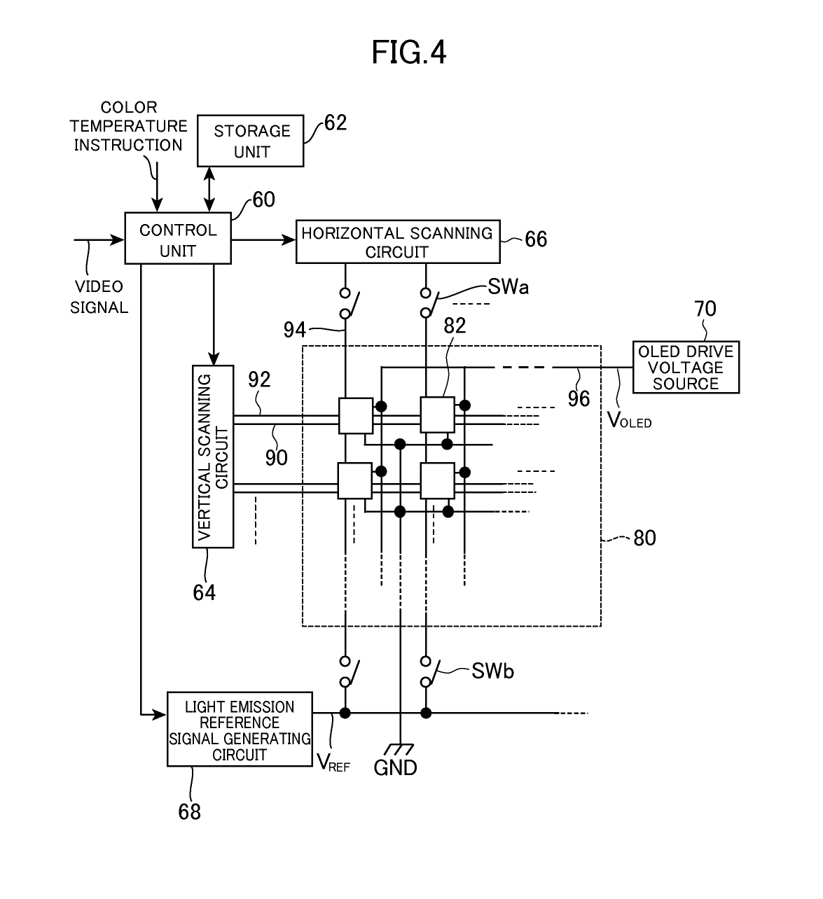

FIG. 4 is a schematic circuit diagram of the organic EL display device of the embodiment, showing a schematic configuration of a portion mainly formed in the display panel 2. In the organic EL display device, a control unit 60, a storage unit 62, a vertical scanning circuit 64, a horizontal scanning circuit 66, a light emission reference signal generating circuit 68, and an OLED drive voltage source 70 are provided as a driver circuit of the display panel 2. Pixel circuits 82 are arranged in a matrix in the display area 80 of the display panel 2. Control lines 90 and 92 are provided in each row (pixel row) of the pixel circuits 82 in the horizontal direction. The pixel circuits 82 constituting each of the pixel rows are connected to the common control lines 90 and 92. The control lines 90 and 92 in each of the rows are connected to the vertical scanning circuit 64. A signal line 94 is provided for each column (pixel column) of the pixel circuits 82 in the vertical direction. The pixel circuits 82 constituting each of the pixel columns are connected to the common signal line 94. The signal line 94 of each of the columns is connected via a switch SWa to the horizontal scanning circuit 66, and connected via a switch SWb to the light emission reference signal generating circuit 68. The pixel circuits 82 are supplied with a positive voltage V_{OLED} from the OLED drive voltage source 70 via a power line 96, and supplied with a ground potential (GND) via a common grounding wire.

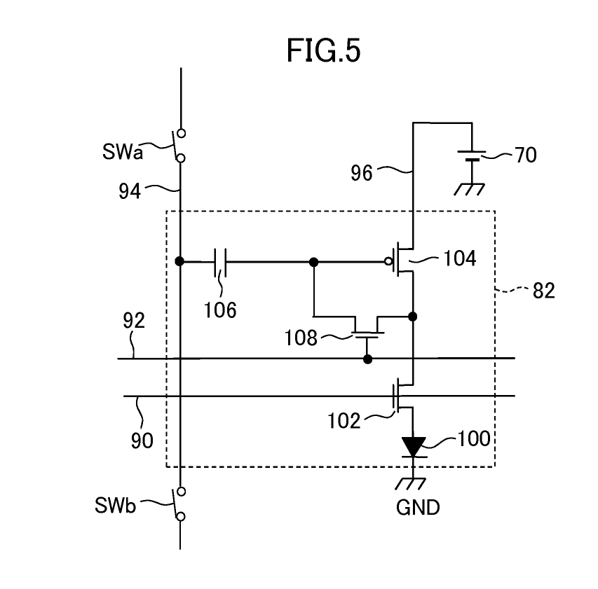

FIG. 5 is a schematic circuit diagram of the pixel circuit 82. An OLED 100 provided in each of the pixel circuits 82 is the white light-emitting OLED described above. A cathode of the OLED 100 is connected to the common grounding wire. An anode of the OLED 100 is connected to the power line 96 via a lighting switch 102 formed of an n-type TFT and a p-type TFT (hereinafter referred to as the drive TFT) 104.

A gate electrode of the drive TFT 104 is connected to the signal line 94 via a storage capacitor 106. A reset switch 108 formed of an n-type TFT is provided between a drain electrode and the gate electrode of the drive TFT 104. The voltage V_{OLED} is applied to a source electrode of the drive TFT 104 from the OLED drive voltage source 70. A gate electrode of the reset switch 108 is connected to the reset control line 92, while a gate electrode of the lighting switch 102 is connected to the lighting control line 90.

The vertical scanning circuit 64 supplies a lighting control signal and a reset control signal for controlling turning on/off of the lighting switch 102 and the reset switch 108 respectively via the lighting control line 90 and the reset control line 92. Specifically, the vertical scanning circuit 64 sequentially selects, using a shift register, a row of the pixel circuits as an operation target in the display area 80 in the column direction (for example, a direction from the upper side to the lower side of a screen), and outputs pulses for turning on the lighting switch 102 and the reset switch 108 to the lighting control line 90 and the reset control line 92 in the selected row.

Data (pixel data) representing image signals of the pixels (sub-pixels) in the row selected by the vertical scanning circuit 64 through vertical scanning is input to the horizontal scanning circuit 66. The horizontal scanning circuit 66 converts the data into an analog voltage with a D/A converter to generate pixel signal voltages in response to the image signals. The horizontal scanning circuit 66 generates the pixel signal voltages for each column of the pixel circuits 82 in the display area 80, and outputs in parallel the pixel signal voltages of the pixels in the selected row to the signal lines 94 in the columns.

As has been described above, the switches SWa and SWb are provided in the signal line 94. With the use of the switches SWa and SWb, the light emission reference signal generating circuit 68, instead of the horizontal scanning circuit 66, can be connected to the signal line 94. Specifically, when the switch SWa is in an on state, the horizontal scanning circuit 66 is connected to the signal line 94. When the switch SWb is in the on state, the light emission reference signal generating circuit 68 is connected to the signal line 94. The switching of the switches SWa and SWb is performed by the control unit 60.

The light emission reference signal generating circuit 68 generates a light emission reference signal of the pixel circuit 82. An output voltage of the light emission reference signal generating circuit 68 is supplied to the pixel circuits 82 via the signal line 94.

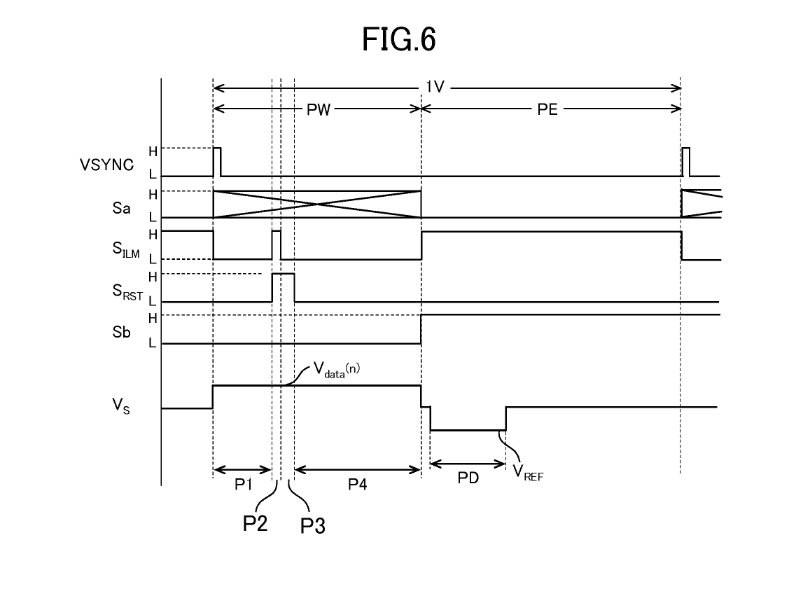

Next, the operation of the pixel circuit will be described. FIG. 6 is a schematic timing diagram explaining the operation of the pixel circuit 82, showing waveforms of various signals in a cycle (1V) of a vertical scanning period. Specifically, FIG. 6 shows a vertical synchronizing signal (VSYNC), a control signal Sa for the switch SWa, a control signal Sb for the switch SWb, a lighting control signal S_{ILM}, a reset control signal S_{RST}, and a voltage V_{S} of the signal line 94. Here, the lighting control signal S_{ILM} and the reset control signal S_{RST} show waveforms relating to an n-th row as anyone line. A period between the rising timings of a vertical synchronizing pulse of VSYNC corresponds to 1V, and display processing on images corresponding to one frame is performed in the period. In the display processing for one frame, processing for writing pixel signal voltages to the pixel circuits 82 is first performed row by row in a writing period PW, and in a subsequent light emission period PE, all lines are caused to emit light at the same time.

Periods P2 and P3 of the writing period PW is a period for a writing operation on the n-th row. Periods P1 and P4 before and after the periods P2 and P3 are periods for the writing operation on up to an (n−1)th row and on an (n+1)th and succeeding rows. In the periods P1 and P4, the vertical scanning circuit 64 maintains the lighting control signal S_{ILM} and the reset control signal S_{RST} for the pixel circuits 82 in the n-th row at a LOW level (hereinafter the L level) as a predetermined low potential. This keeps the lighting switch 102 and the reset switch 108 in an off state, so that the gate electrode of the drive TFT 104 maintains a charge storage state set in the writing operation of the previous frame.

In the periods P2 and P3 as the period for the writing operation on the n-th row, a pixel signal voltage V_{data}(n) of the n-th row is applied from the horizontal scanning circuit 66 to the signal line 94. In the period P2, the vertical scanning circuit 64 sets the lighting control signal S_{ILM} and the reset control signal S_{RST} to a HIGH level (hereinafter the H level) as a predetermined high potential. This brings the lighting switch 102 and the reset switch 108 into the on state, so that the charge stored on the gate side of the drive TFT 104 according to the pixel signal voltage of the previous frame is discharged to the ground potential (GND) via the OLED 100. This operation is referred to as a reset operation, in which preparation for writing a signal in response to the pixel signal voltage V_{data}(n) of the current frame to the storage capacitor 106 is made. In this case, because of the discharging from the gate of the drive TFT 104 and turning on of the drive TFT 104 due to lowering of a gate potential V_{G}, a current flows into the OLED 100. This causes the OLED 100 to emit light, but the light emission occurs in a very short time, so that an influence on a video is small.

In the period P3, the lighting control signal S_{ILM} is set to the L level, so that the lighting switch 102 is brought into the off state. The reset switch 108 maintains its on state to connect the gate of the drive TFT 104 with the drain thereof. This brings the drive TFT 104 into a so-called diode connection state, so that a current flows from the power line 96 into the storage capacitor 106 via the drive TFT 104 in the on state. The current flows until a gate-source voltage V_{GS} of the drive TFT 104 reaches a threshold voltage Vₜₕ. In a state where the current stops or becomes sufficiently small, the potential of the gate of the drive TFT 104 and one of terminals of the storage capacitor 106 is (V_{OLED}+Vₜₕ).

In the period P3, since the voltage V_{data}(n) is applied to the other terminal of the storage capacitor 106 connected to the signal line 94, a potential difference (V_{OLED}+Vₜₕ−V_{data}(n)) is set between the terminals of the storage capacitor 106. When the period P3 ends, the reset control signal S_{RST} is set to the L level, the reset switch 108 is brought into the off state, the gate of the drive TFT 104 and the one terminal of the storage capacitor 106 are brought into a floating state, and the storage capacitor 106 holds the potential difference (V_{OLED}+Vₜₕ−V_{data}(n)) in response to the pixel signal voltage of the n-th row.

When the cycle enters the light emission period PE, the switch SWa is turned off, while the switch SWb is turned on. Due to this, a pulse having a light emission reference voltage V_{REF} is supplied from the light emission reference signal generating circuit 68 to the signal lines 94 in the columns. The pulse is applied in common to the storage capacitors 106 of the pixel circuits 82 of each of the columns. Here, the reset switch 108 of the pixel circuit 82 is turned off, and the terminal of the storage capacitor 106 on the drive TFT 104 side is in the floating state, and therefore, the potential of the terminal shifts according to the potential of the terminal of the storage capacitor 106 on the signal line 94 side, that is, according to V_{REF}. As a result, for example, the gate potential V_{G} of the drive TFT 104 in the n-th row is (V_{OLED}+Vₜₕ−V_{data}(n)+V_{REF}), and the gate-source voltage V_{GS} is (Vₜₕ−V_{data}(n)+V_{REF}).

In a state where V_{GS} is set as described above, the vertical scanning circuit 64 sets the lighting control signal S_{ILM} of each pixel row to the H level to turn on the lighting switch 102. Due to this, a drain current in response to the V_{GS} described above flows into the drive TFT 104. Then, the drain current is supplied to the OLED 100, so that the OLED 100 emits light according to the amount of the current.

Incidentally, since V_{GS} is set to (Vₜₕ−V_{data}(n)+V_{REF}), even when the threshold voltage Vₜₕ of the drive TFT 104 varies, the amount of current to be supplied to the OLED 100 is not affected by Vₜₕ, and determined according to the pixel signal voltage V_{data}(n) and the light emission reference voltage V_{REF}. Moreover, it is understood that V_{REF} determines the threshold of the pixel signal voltage V_{data} with which the OLED 100 emits light. That is, if the relation of V_{data}(n)≧V_{REF} is satisfied, the drive TFT 104 that is of p-channel type is turned on to cause the OLED 100 to emit light; while if the relation of V_{data}(n)<V_{REF} is satisfied, the drive TFT 104 is not turned on, thereby not causing the OLED 100 to emit light.

The light emission reference signal generating circuit 68 outputs V_{REF} with which the OLED 100 can emit light in an actual light emission period PD included in the light emission period PE, and basically outputs, in the light emission period PE other than PD, a voltage with which the OLED 100 does not emit light for the pixel signal voltage V_{data} corresponding to the maximum value of pixel data.

The width and voltage of the output pulse of the light emission reference signal generating circuit 68, that is, the length of the period PD and the value of V_{REF} are controlled by the control unit 60. To the organic EL display device according to the embodiment, an instruction relating to the color temperature (hue) of a display image can be input from a user. The color temperature instruction is input to the control unit 60. The control unit 60 controls the length of the period PD and V_{REF} based on the color temperature instruction.

Here, when V_{REF} is changed, a drive current flowing into the OLED 100 changes, and a change in the current density of the drive current causes a change in the luminescent color of the OLED 100. The display panel 2 uses this phenomenon to change the hue of light emission based on the color temperature instruction, which enables the adjustment of the color temperature.

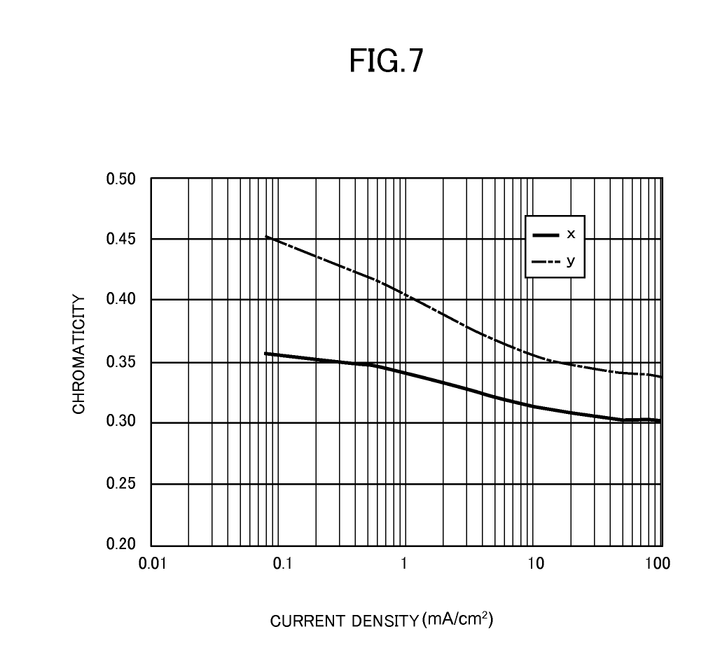

Specifically, when the emission spectrum of the OLED 100 was measured while changing the current density, blue light emission remarkably increased, compared to changes in the amount of light emission of red and green light emission, as the current density increased. FIG. 7 is a graph showing an example of the result of measuring the relationship between the current density of the drive current to be supplied to the OLED 100 and the chromaticity of the OLED 100. The horizontal axis represents the current density on a logarithmic scale, while the vertical axis represents the X- and Y-values of coordinates (X and Y) on an XY chromaticity diagram of the luminescent color of the OLED 100. When the current density was changed from 0.08 to 100 mA/cm², the X-value changed from 0.36 to 0.30 and the Y-value changed from 0.45 to 0.34 in the chromaticity of the white light-emitting OLED. This corresponds to a change in correlated color temperature from about 5200 K to 7000 K. It is considered that the change in hue in response to the current density is caused by a change in the balance of carriers (holes and electrons) flowing into each of the light-emitting units.

When the current density changes, the emission intensity of the OLED also changes in response thereto. Basically, the emission intensity changes in proportion to the current density. Therefore, when changing the drive current of the OLED so that the light emission of the OLED produces the hue in response to a color temperature instruction, the control unit 60 changes the actual light emission period PD in inverse proportion to the change in drive current so as to maintain emission luminance before and after the change in drive current. That is, the control unit 60 changes a light emission duty in the light emission period PE.

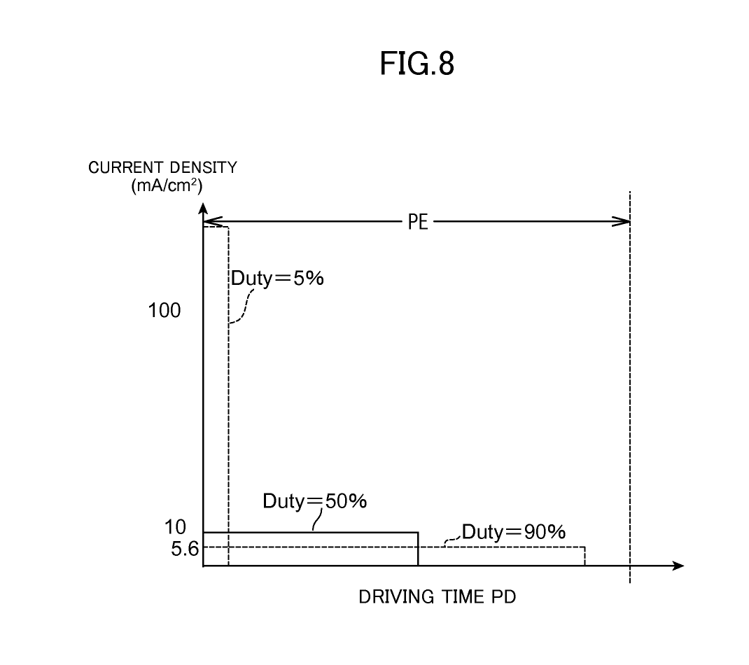

FIG. 8 is a schematic diagram showing an example of a change in light emission duty in response to a change in current density, in which the vertical axis corresponds to the current density, while the horizontal axis corresponds to the driving time PD. In this example, a light emission duty defined by PD/PE when the current density at the maximum pixel value is 10 mA/cm² is set to 50%. Incidentally, in the example shown in FIG. 7, the XY chromaticity under this driving condition is (0.31, 0.36), which corresponds to about 6500 K in correlated color temperature.

For example, the control unit 60 sets the actual light emission period PD at each current density so that the luminance (the amount of light emission in the light emission period PE) at the maximum pixel value is constant without depending on the current density. For example, when setting the current density to 100 mA/cm² for obtaining light emission at (0.30, 0.34) in XY chromaticity, which corresponds to about 7000 K in correlated color temperature, the control unit 60 sets the light emission duty to 5%. Moreover, when setting the current density to 5.6 mA/cm² for obtaining light emission at (0.32, 0.37) in XY chromaticity, which corresponds to about 6000 K in correlated color temperature, the control unit 60 sets the light emission duty to 90%. In this manner, even when the current density changes, the average current density in one frame period does not change due to the adjustment of the light emission duty, so that the luminance on image display is kept constant.

Although, in this case, the luminance is kept constant with the luminance at the maximum pixel value as a reference, a luminance at another pixel value may be used as a reference. Moreover, the control unit 60 can be configured so as to change the level of the luminance to be kept constant. For example, the control unit 60 can be configured such that, in the organic EL display device, the brightness of a screen can be adjusted and set by a user or can be automatically adjusted and set by detecting ambient brightness, and that the brightness set in such a manner is maintained when the current density changes.

Incidentally, the inverse proportional relationship between the drive current and the actual light emission period PD described above should not be construed in a strict sense, but should be construed according to the purpose of maintaining the emission luminance before and after a change in current density, and the inverse relationship includes an approximate inverse relationship. For example, the luminous efficiency of the OLED 100 is not always constant for the current density, and the current density and the emission intensity are not always precisely proportional to each other. Moreover, the relationship between V_{REF} and the current density is not always linear. Therefore, the control unit 60 can be configured such that when, for example, low accuracy in controlling the color temperature and the luminance is permitted, the length of the actual light emission period PD corresponding to V_{REF} or the current density is obtained by an arithmetic operation based on the proportional or inverse proportional relationship. However, when high accuracy is required, the control unit 60 is configured so as to control the color temperature and the luminance based on a previously measured result.

Specifically, the correspondence relationship between V_{REF} or the current density and the actual light emission period PD, or the current density dependence of the luminous efficiency is previously evaluated by measurement, and the result of measurement is stored in the storage unit 62. Then, the control unit 60 performs control for adjusting the color temperature based on the result of measurement while keeping the luminance constant.

Here, the color temperature instruction, V_{REF}, the current density, the color temperature, and the light emission duty are correlated to each other, and the correlation previously stored in the storage unit 62 can have various forms. For example, the storage unit 62 can previously store a value representing V_{REF} and a value representing PD corresponding to the color temperature instruction. In this case, when the color temperature instruction is input to the control unit 60, the control unit 60 reads, using the color temperature instruction as a key, the values representing V_{REF} and PD from the storage unit 62, and controls the light emission reference signal generating circuit 68 based on the values to output, in the light emission period PE, a pulse whose pulse voltage and pulse width are respectively V_{REF} and PD that correspond to the values.

According to the organic EL display device of the embodiment, an assembly manufacturer that manufactures an organic EL display device using the display panel 2 can adjust the color temperature of the display panel 2, when designing the organic EL display device, to obtain a desired characteristic relating to the hue of an image. That is, it is not needed to design or manufacture a display panel in which the color temperature of a white light emitting OLED is changed depending on products, which is advantageous for reducing cost. For example, the assembly manufacturer initializes the current density so as to obtain a preferred color temperature depending on the type of the product, or adjusts the current density so as to obtain an aimed color temperature for each individual product in shipping inspection. Further, by adjusting the color temperature using the driving of the OLED described above, it is possible to omit processing for adjusting the hue of an image through video signal processing with a peripheral system or to achieve a reduction in the load of the processing. Moreover, a finer adjustment can be made by combining the adjustment of hue through the video signal processing with the above-described color temperature adjustment by driving the OLED.

The user who gives a color temperature instruction is not only an assembly manufacturer but may be an end user who uses an organic EL display device. For example, the user can adjust the color temperature to the use's preference depending on an image that the user views or illumination at an installation site. The organic EL display device allowing the end user to adjust the color temperature of the display panel 2 has high added value as a product.

Inputting a color temperature instruction to the organic EL display device is possible through, for example, an on-screen display (OSD). A means of inputting a color temperature instruction may have another configuration. For example, it is possible to allow the user to operate a hardware component such as a dedicated knob or switch to input an electric signal generated by the operation to the control unit 60, or to allow the user to operate a remote control of the organic EL display device.

Although a case has been described in the embodiment in which the white light-emitting OLED has a tandem structure formed of two light-emitting units, the invention is not limited to this structure. For example, the white light-emitting OLED may have a tandem structure formed of three or more light-emitting units. Moreover, the invention can be applied also to the case where the white light-emitting OLED is an OLED in which dopant materials (light-emitting materials) of a plurality of colors are mixed in a single layer or the case where the white light-emitting OLED is an OLED in which light-emitting layers of a plurality of colors are directly stacked.

Here, in the OLED that generates white light by mixing lights from plural kinds of dopants that emit lights of different colors from each other, it is known that light emission occurs preferentially from a dopant molecule whose luminescent color has a long wavelength, that is, whose excitation energy level is low. Therefore, the contents of plural kinds of dopant materials in a light-emitting layer are set such that the shorter the wavelength of the luminescent color is, the higher the content is, so that the adjustment width of the color temperature can be expanded. For example, in an OLED containing R, G, and B dopants, by setting the amount of the B dopant higher than the R and G dopants, a range of capable of increasing light emission of the B dopant is widened after light emission of the R and G dopants is saturated when the current density is increased, making it possible to obtain a higher color temperature to widen the adjustment range of the color temperature.

According to the invention described using the embodiment, with the use of a change in the hue of light emission in response to the current density of the drive current flowing into the white light-emitting OLED, display panels whose OLEDs have a common structure can be used for a plurality of organic EL display devices that require different color temperatures for display panels. Therefore, a burden in designing and manufacturing an OLED is reduced, and also, a reduction in the cost of the organic EL display device can be achieved. Moreover, the hue of an image can be easily adjusted in individual organic EL display devices.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A driving method of an organic EL display device in which organic light-emitting elements each of which includes a light-emitting layer containing a plurality of light-emitting materials of different colors and emits light in response to a drive current are two-dimensionally arranged, the method comprising:
changing the drive current to be supplied to the organic light-emitting element so that light emission of the organic light-emitting element produces a hue in response to an instruction from a user; and
changing a light emission duty of the organic light-emitting element in inverse proportion to a change in the drive current so as to maintain emission luminance before and after the change in the drive current.

2. The driving method of the organic EL display device according to claim 1, wherein
the light-emitting layer includes a plurality of different colored light-emitting layers that are stacked, the plurality of different colored light-emitting layers containing light-emitting materials of different colors from each other.

3. The driving method of the organic EL display device according to claim 2, wherein
the organic light-emitting element has a tandem structure in which a plurality of light-emitting units of different colors are connected in series.

4. The driving method of the organic EL display device according to claim 1, wherein
the contents of the plurality of light-emitting materials in the light-emitting layer are such that the shorter the wavelength of a luminescent color is, the higher the content is.

5. An organic EL display device in which an organic light-emitting element that includes a light-emitting layer containing a plurality of light-emitting materials of different colors and emits light in response to a drive current is arranged in each of pixels, comprising:
a pixel circuit to which a light emission control pulse having a pulse width defining a light emission duty is input and that supplies to the organic light-emitting element the drive current at a current density in response to a pixel value in response to an image to be displayed and a pulse voltage of the light emission control pulse;
a storage unit that stores a correlation between the pulse voltage and a luminescent color of the organic light-emitting element changing in response to the drive current; and
a driver circuit to which an instruction relating to a luminescent color from a user is input and that supplies to the pixel circuit the light emission control pulse in response to the instruction, the driver circuit setting, based on the correlation, the pulse voltage corresponding to the luminescent color according to the instruction and changing, for a change in the pulse voltage, the pulse width in inverse proportion to the change in the drive current in response to the pulse voltage.
